(19) United States
(12) Patent Application Publication
(10) Pub. No.: US 2019/0280572 A1
(43) Pub. Date: Sep. 12, 2019

(54) Actuation Device

(71) Applicant: SBS-Feintechnik GmbH & Co. KG, Schonach (DE)

(72) Inventors: Philipp Wöhrle, Triberg (DE); Uwe Gnauert, Villingen-Schwenningen (DE)

(21) Appl. No.: 16/294,990

(22) Filed: Mar. 7, 2019

(30) Foreign Application Priority Data
Mar. 9, 2018 (DE) 10 2018 002 063.1

(51) Int. Cl. H02K 11/38

(52) U.S. Cl. CPC H02K 11/38; H05K 2201/1059

(57) ABSTRACT

An actuation device has a motor with a motor shaft and with at least one motor contact and/or sensor contact. A circuit board with at least one electronic circuit is provided. The motor is electrically connected by an electric connection to the circuit board. The motor contact and/or sensor contact is a press-fit contact pressed into at least one contact of the circuit board to produce the electric connection.

### BACKGROUND OF THE INVENTION

The invention relates to an actuation device comprising a motor that comprises a motor shaft, is connected to an electronic circuit disposed on at least one circuit board, and comprises at least one motor contact and/or sensor contact producing an electric connection to the circuit board.

Actuation devices in the form of actuators are known with which, for example, throttle valves of a motor vehicle are actuated. The actuators have a motor that is electrically connected to an electronic control circuit on the circuit board. The motor has motor contacts and in general also sensor contacts. The motor contacts are, for example, connected to Hall sensors used for electronic commutation of the electric motor. The sensor contacts are, for example, connected to temperature sensors which detect the windings temperature of the electric motor, for example. The contacts are embodied as soldered contacts. Therefore, automated contacting is difficult to perform.

Actuators are also known in which electric contacting is produced by clip contacts. These clip contacts however constitute an additional component so that the manufacture of the actuator is not only made more expensive but also more difficult.

It is an object of the invention to embody an actuation device of the aforementioned kind such that the connection of the contacts of the motor with the electronic circuit on the circuit board can be produced in a simple and inexpensive way.

### SUMMARY OF THE INVENTION

In accordance with the invention, the object is achieved in that the motor contact and/or sensor contact is embodied as a press-fit contact that produces the electric connection when pressed into at least one contact of the circuit board.

In the actuation device according to the invention, the motor contact and/or sensor contact is embodied as a press-fit contact which is pressed into the contact of the circuit board. The use of the press-fit contact provides for considerable cost savings because additional components for contacting are not required. The press-fit contact can be connected simply with the circuit board. In particular, contacting can be automated so that the actuation device can be produced inexpensively even as a mass-produced product. The environmental problems associated with soldering are avoided. A compact configuration can be achieved with the press-fit contact. Also, by using the press-fit contact, additional electric lines are avoided so that an optimized electromagnetic compatibility is achieved.

In an advantageous embodiment, the press-fit contact extends parallel to the motor shaft. The press-fit contact can thus be connected very easily to the corresponding counter contacts of the circuit board. Such an arrangement of the press-fit contact is in particular advantageous when a spur gear of a spur gear unit is provided, for example, on the motor shaft projecting past the circuit board. In this case, the axis-parallel press-fit contact can be contacted on the circuit board immediately adjacent to this spur gear.

In such a case, the circuit board extends parallel to an end plate of the motor. The press-fit contact projects past the end plate. The circuit board itself is provided with a correspondingly large through opening to enable passage of the motor shaft as well as the gear wheel seated thereon.

In another advantageous embodiment, the press-fit contact is configured and arranged such that it extends transversely, preferably perpendicularly, to the motor shaft. Such a configuration is in particular advantageous when a worm gear of a worm gear unit is attached to the motor shaft projecting from the motor housing. In this case, the worm gear as well as the press-fit contact are positioned at different ends of the motor housing. The circuit board is advantageously positioned transversely, preferably perpendicularly, to the end plate of the motor in such a configuration.

In such a configuration, the circuit board is not penetrated by the motor shaft so that the circuit board can be designed to be correspondingly small.

When the press-fit contact is extending transversely to the motor shaft, the insertion direction of the press-fit contact is oriented also transversely to the motor shaft, preferably perpendicularly thereto. Such a configuration enables a very compact configuration of the actuation device because the circuit board can be designed such that it is provided close to the motor housing.

In an advantageous embodiment, the actuation device is an actuator by means of which adjustable elements such as flaps or valves can be actuated. The elements to be adjusted are in driving connection with the motor shaft of the motor by means of a gear system such as a spur gear unit or a worm gear unit. In case of a spur gear unit, a spur gear is seated on the end of the motor shaft projecting from the motor housing; in case of a worm gear unit, a worm gear is seated on the end of the motor shaft.

The motor is advantageously an electric motor and can be a direct-current motor with brushes but can also be a brushless direct-current motor.

The electronic circuit disposed on the circuit board is advantageously an electronic control circuit with which the respective adjustable element can be adjusted position-precisely in the respective desired or required position.

The subject matter of the invention not only results from the claimed subject matter of the individual claims but also from all features and specifications disclosed in the drawings and in the description. Even if such features and specifications are not subject matter of the claims, they are claimed as important to the invention insofar as, individually or in combination, they are novel compared to the prior art.

Further features of the invention result from the additional claims, the description, and the drawings.

### BRIEF DESCRIPTION OF THE DRAWING

The invention will be explained with the aid of two embodiments illustrated in the drawings.

FIG. 1 is a perspective illustration of a first embodiment of an actuation device according to the invention.

FIG. 2 is a side view of the actuation device according to FIG. 1.

FIG. 3 is a further side view of the actuation device according to FIG. 1.

FIG. 4 is a perspective illustration of a second embodiment of an actuation device according to the invention.

FIG. 5 is a plan view of the actuation device according to FIG. 4.

FIG. 6 is a side view of the actuation device according to FIG. 4.

FIG. 7 is a schematic illustration of a valve flap which is actuated by the actuation device according to the invention.

FIG. 8 is a perspective illustration of an electric motor of the actuation device according to the invention with different sensors to which contacts are connected.

### DESCRIPTION OF THE PREFERRED EMBODIMENTS

The actuation device comprises an electric motor with a motor housing 1 in which the motor components (not illustrated) are accommodated. In the illustrated embodiment, the motor housing 1 is of a cylindrical configuration. Depending on the field of use, the motor housing 1 can also have a different configuration.

The motor housing 1 comprises a bottom 2 and a cover 3. A motor shaft 4 is rotatably supported at a bearing 5 arranged at the exterior side of the bottom 2.

The motor shaft 4 projects past the cover 3 which forms an end plate. The motor shaft 4 penetrates a circuit board 6 which forms part of the actuation device. On the circuit board 6, electric/electronic components of an electronic control circuit are provided and electrically connected to the motor.

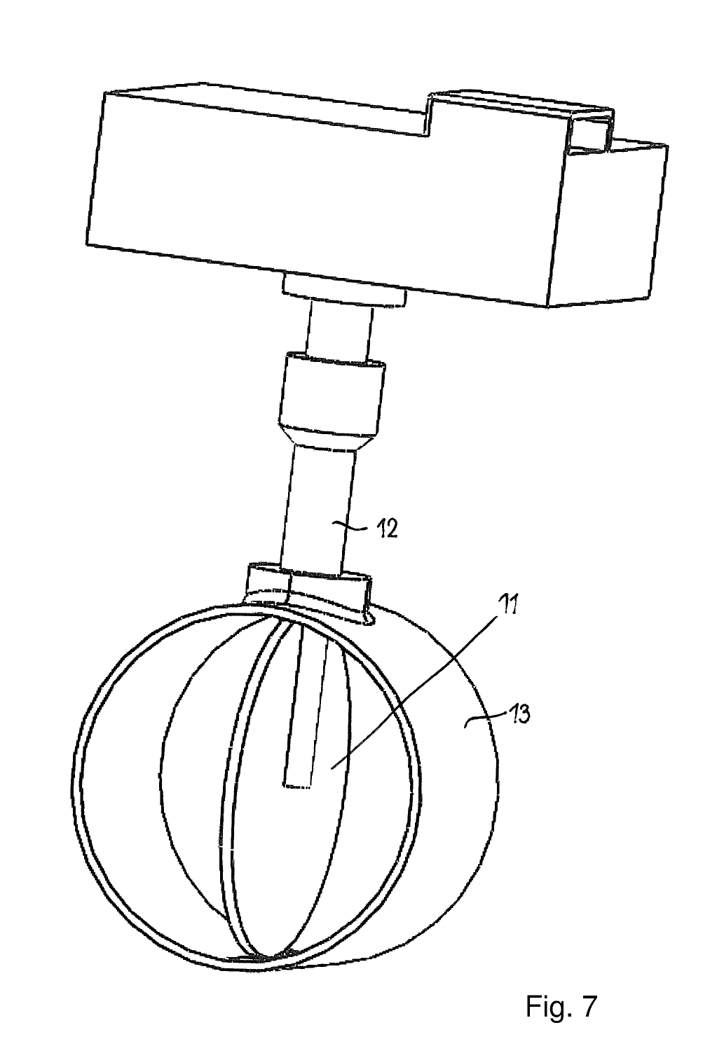

The actuation device is advantageously an actuator with which, for example, flaps 11 of an internal combustion engine of motor vehicles can be actuated (see FIG. 7). Such flaps can be disposed in the exhaust gas manifold, in suction pipes, and the like. By means of the actuator, such flaps can be adjusted with high precision. The actuation device moreover can also be used for electric motors or cooling systems in order to actuate corresponding control members such as valves that are associated with the electric motors or cooling systems.

In the embodiment illustrated in FIG. 7, the flap 11 is seated on a shaft 12 that can be rotated by means of the electric motor about its axis. The flap 11 is arranged in a pipe 13 through which a medium, for example, exhaust gas, flows. The flow cross section of the pipe 13 can be adjusted as a function of the position of the flap 11.

In the region of the cover 3, the motor shaft 4 is rotatably supported by a bearing 7 arranged in the region between the cover 3 and the circuit board 6.

The circuit board 6 is provided with a through opening 10 for passage of the motor shaft 4.

For electric contacting of the motor with the electronic control circuit which is provided on the circuit board 6, two contacts 8 are provided, for example; they extend in axial direction of the motor and are embodied as press-fit contacts. The two contacts 8 are positioned in the region adjacent to the motor shaft 4 and penetrate corresponding openings (through contacts) 9 in the circuit board 6 and provide, as is known in the art, the electrical contact between the motor and the electronic control circuit on the circuit board 6. Depending on the type of application, the appropriate press-fit contacts are employed as contacts 8 which are pressed into the provided through contacts 9.

The contacts 8 which are positioned parallel to the motor shaft 4 are advantageously used for actuators with a spur gear unit. In such a case, a spur gear is seated on the end of the motor shaft 4 projecting past the circuit board 6. The circuit board 6 is positioned parallel to the cover or end plate 3.

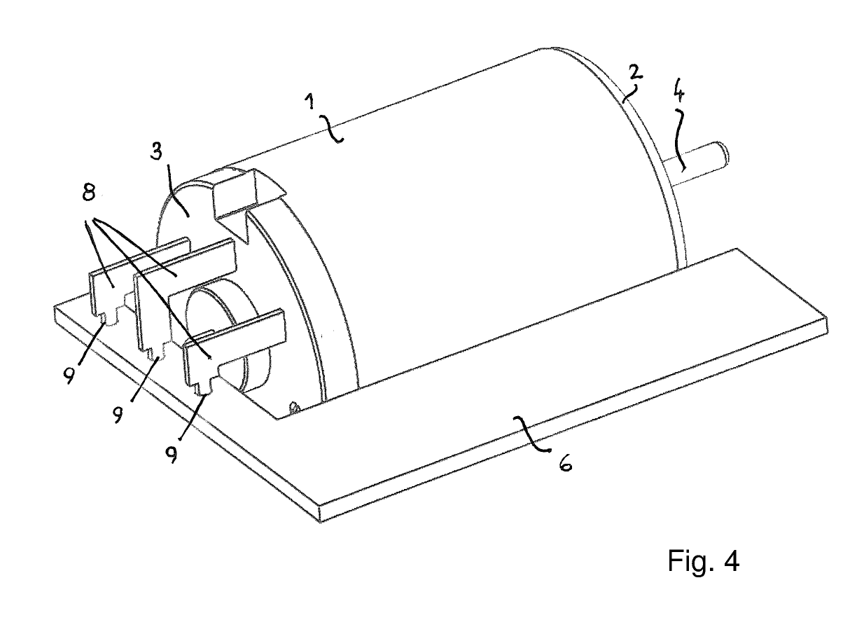

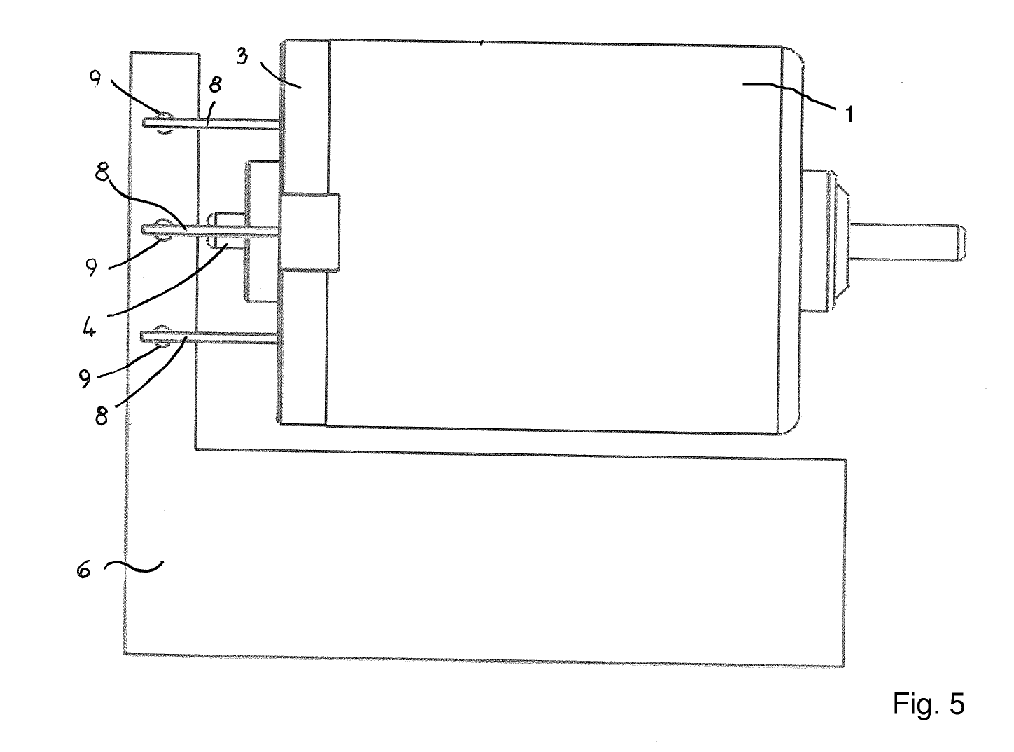

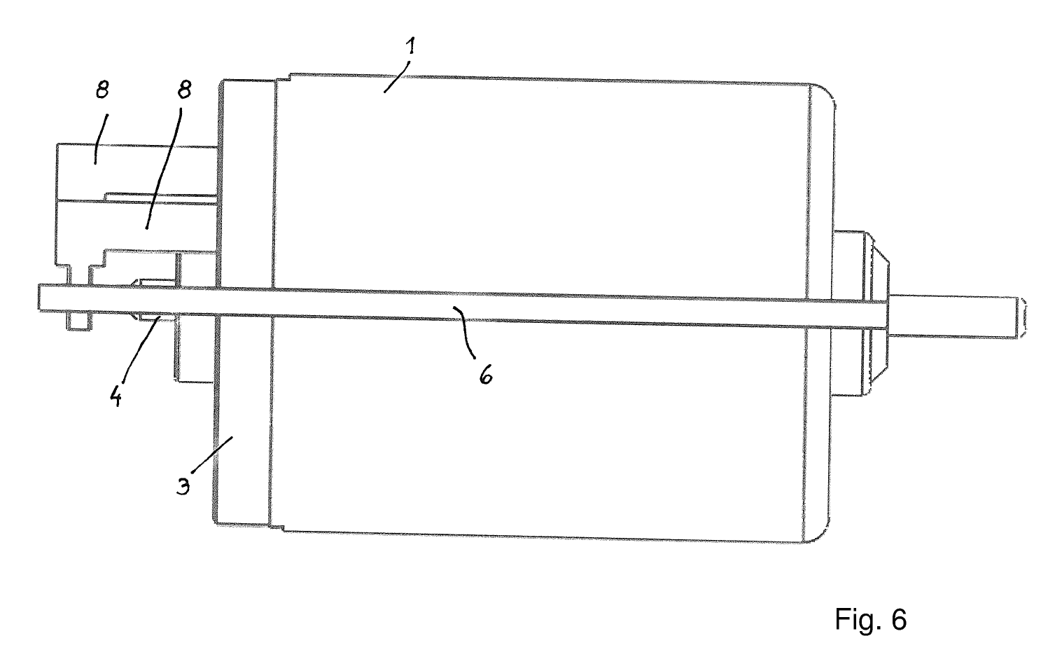

In the embodiment according to FIGS. 4 to 6, the circuit board 6 is arranged perpendicular to the end plate 3. For example, the circuit board 6 is L-shaped. It extends along the wall of the motor housing 1 as well as with its short narrow leg parallel to the end plate 3.

The contacts 8 project from the end plate 3 and are L-shaped. The contacts 8 are also press-fit contacts which extend parallel to the motor shaft 4 and whose angled ends engage the openings 9 of the circuit board 6 with press fit.

The contacts 8 are positioned parallel to each other as well as perpendicular to the end plate 3. Advantageously, the openings 9 in the narrow circuit board part are arranged along a straight line one behind the other along this circuit board part.

This configuration and orientation of the press-fit contacts 8 is advantageously suited for actuators with worm gear units. In this embodiment, a worm gear (not illustrated) that is part of the worm gear unit is positioned on the part of the motor shaft 4 projecting past the bottom 2 of the motor housing 1. The contacts 8 are provided at the opposite end of the motor housing 1.

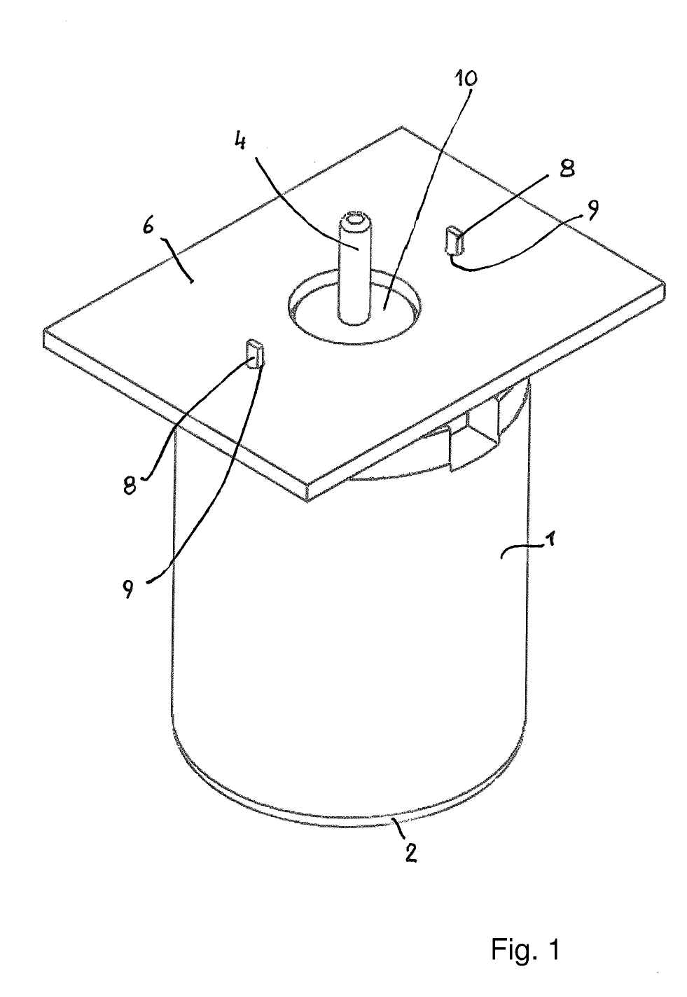

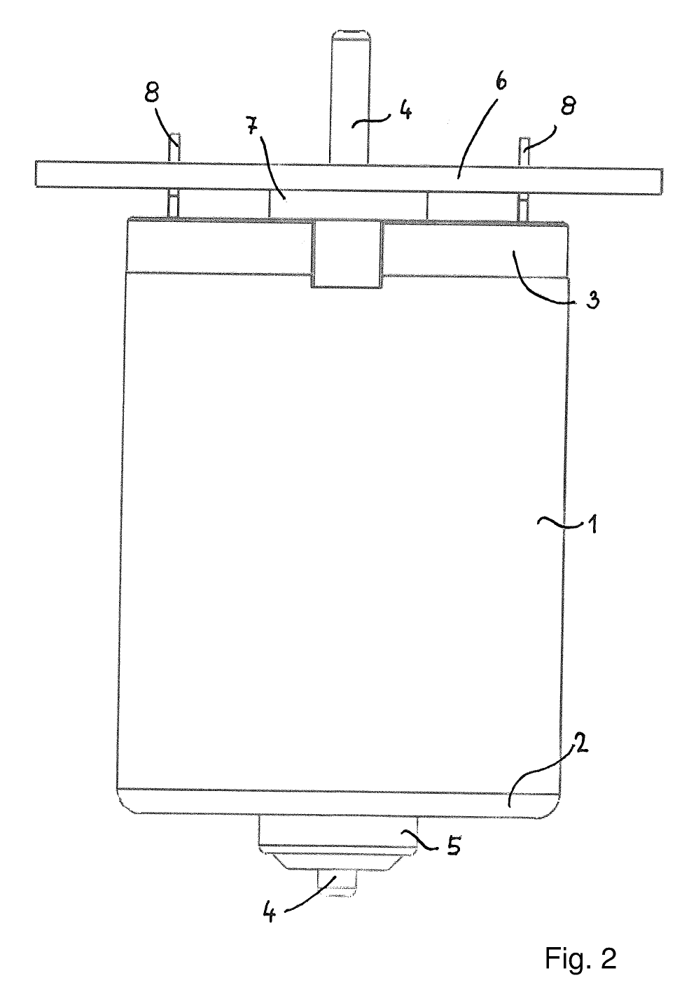

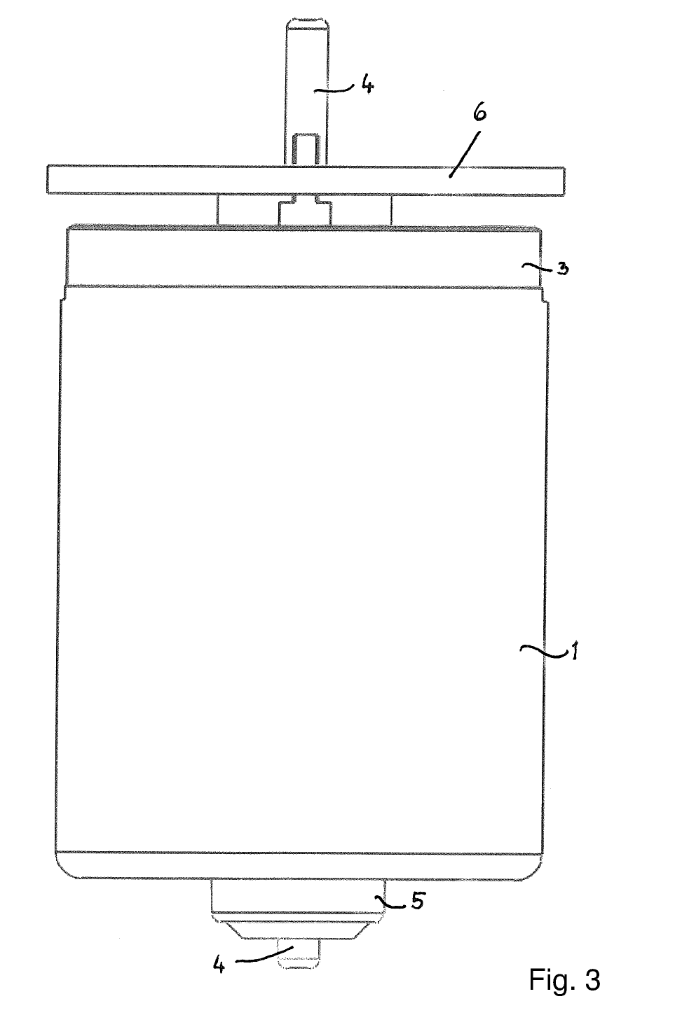

The orientation of the press-fit contacts 8 is illustrated and described in FIGS. 1 through 6 only in an exemplary fashion. Depending on the configuration of the motor and/or of the circuit board 6, the press-fit contacts 8 can also have different orientations.

The motor according to FIGS. 1 to 3 with the two contacts 8 is a direct-current motor with brushes. The motor according to FIGS. 4 to 6 with three contacts 8 is a brushless direct-current motor.

By means of the press-fit contacts 8, a simple contacting of the motor with the circuit board 6 is possible. In particular, contacting can be carried out by automation which is in particular advantageous in case of mass production. For contacting, no additional components such as clip contacts are required. By means of press-fit contacts, a compact configuration and thus a geometric minimization of the entire drive is possible.

The use of the press-fit contacts 8 leads to an optimized electromagnetic compatibility because additional electrical lines are obsolete.

The motor can advantageously be used as a small motor, for example, in a performance range of up to 50 W of mechanical power. The motor can be used in particular for actuators. Also, the motor can be used, for example, for opening or closing valves, for example, in an exhaust gas devices or cooling circuits.

The press-fit contacts 8 are pressed in a known manner into the openings 9 provided for them in order to achieve through contacting at the circuit board 6.

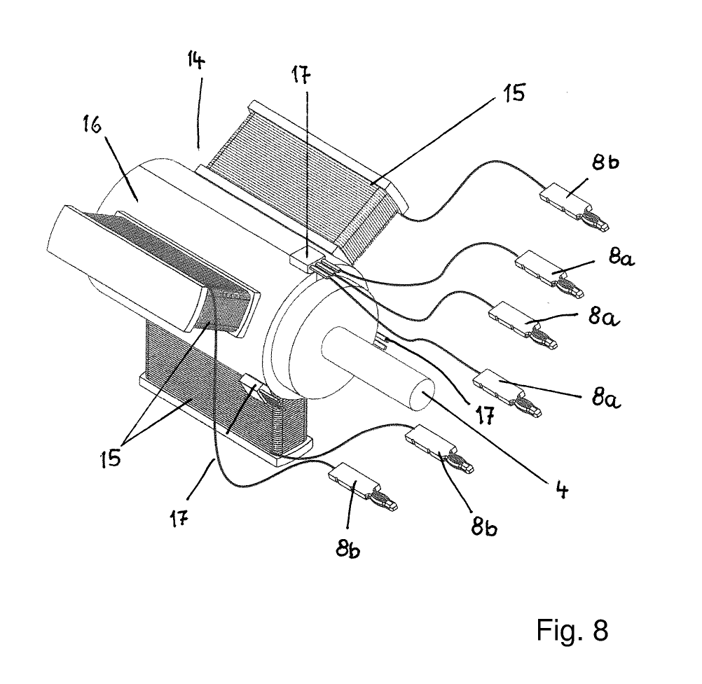

As can be seen in an exemplary fashion in FIG. 8, the contacts 8 can be motor contacts and sensor contacts. FIG. 8 shows a stator 14 with windings 15. The stator 14 surrounds a rotor 16 that comprises the motor shaft 4 as a rotor shaft and is provided about its circumference with permanent magnets. The motor which is illustrated in an exemplary fashion is an internal rotor motor.

The motor windings 15 are provided with integrated sensor means in the form of three Hall sensors 17 that serve for commutating the electric motor. The electrical connection between the Hall sensors 17 and the corresponding contacts on the circuit board 6 is realized through the press-fit contacts 8a which form motor contacts.

Moreover, the electric motor is provided with temperature sensors (not illustrated) that are electrically connected by corresponding lines with the sensor contacts 8b. The sensor contacts 8b are formed in the described way as press-fit contacts with which in particular an automated contacting can be ensured in a simple way.

The specification incorporates by reference the entire disclosure of German priority document 10 2018 002 063.1 having a filing date of Mar. 9, 2018.

While specific embodiments of the invention have been shown and described in detail to illustrate the inventive principles, it will be understood that the invention may be embodied otherwise without departing from such principles.

What is claimed is:

1. An actuation device comprising:
a motor comprising a motor shaft and further comprising at least one motor contact and/or sensor contact;
a circuit board comprising at least one electronic circuit;
wherein the motor is electrically connected by an electric connection to the circuit board;
wherein the motor contact and/or sensor contact is a press-fit contact pressed into at least one contact of the circuit board to produce the electric connection.

2. The actuation device according to claim 1, wherein the press-fit contact extends parallel to the motor shaft.

3. The actuation device according to claim 2, wherein the circuit board is positioned parallel to an end plate of the motor.

4. The actuation device according to claim 1, wherein the press-fit contact extends transversely to the motor shaft.

5. The actuation device according to claim 4, wherein the circuit board extends transversely to an end plate of the motor.

6. The actuation device according to claim 1, wherein an insertion direction of the press-fit contact into the at least one contact of the circuit board extends perpendicularly to the motor shaft.

7. The actuation device according to claim 1, wherein the actuation device is an actuator.

8. The actuation device according to claim 1, wherein the motor is a direct-current motor with brushes.

9. The actuation device according to claim 1, wherein the motor is a brushless direct-current motor.

10. The actuation device according to claim 1, wherein the at least one electronic circuit is an electronic control circuit.
